(19) United States
(12) Patent Application Publication
(10) Pub. No.: US 2017/0067163 A1
(43) Pub. Date: Mar. 9, 2017

(54) MULTIPLE CHAMBER CHEMICAL VAPOR DEPOSITION SYSTEM

(71) Applicant: Veeco Instruments Inc., Plainview, NY (US)

(72) Inventors: George Papasouliotis, Warren, NJ (US); Miguel Saldana, Aptos, CA (US); Brett Snowden, Manasquan, NJ (US); Yuliy Rashkovsky, Millburn, NJ (US); Michael Pacier, Bath, PA (US)

(21) Appl. No.: 15/245,706

(22) Filed: Aug. 24, 2016

Related U.S. Application Data
(60) Provisional application No. 62/213,950, filed on Sep. 3, 2015.
(60) Provisional application No. 62/317,085, filed on Apr. 1, 2016.

(51) Int. Cl. C23C 16/52; C23C 16/50; H01L 21/683; H01L 21/02; H01L 21/687; C23C 16/455; C23C 14/22

(52) U.S. Cl. CPC C23C 16/52; C23C 16/45544; C23C 16/50; C23C 14/22; H01L 21/0262; H01L 21/0254; H01L 21/02529; H01L 21/68785; H01L 21/68764; H01L 21/6838

(57) ABSTRACT

A chemical vapor deposition system is disclosed herein. The chemical vapor deposition system has a plurality of reaction chambers to operate independently in the growth of epitaxial layers on wafers within each of the reaction chambers for the purpose of reducing processing time while maintaining the quality necessary for the fabrication of high-performance semiconductor devices.

### RELATED APPLICATION INFORMATION

This application claims the benefit of U.S. Provisional Application 62/213,950, filed Sep. 3, 2015, and U.S. Provisional Application 62/317,085, filed Apr. 1, 2016, both of which are hereby incorporated by reference.

### TECHNICAL FIELD

The present disclosure relates generally to semiconductor fabrication technology. More particularly, the present disclosure relates to a chemical vapor deposition system having a plurality of reaction chambers configured to operate independently in the growth of epitaxial layers on substrates.

### BACKGROUND

Certain processes for fabrication of semiconductors can require a complex process for growing epitaxial layers to create multilayer semiconductor structures for use in fabrication of high performance devices, such as light emitting diodes, laser diodes, optical detectors, power electronics, and field effect transistors. In this process, the epitaxial layers are grown through a general process called Chemical Vapor Deposition (CVD). One type of CVD process is called Metal Organic Chemical Vapor Deposition (MOCVD). In MOCVD, a reactor gas is introduced into a sealed reactor chamber within a controlled environment that enables the reactor gas to be deposited on a substrate (commonly referred to as a wafer) to grow thin epitaxial layers. Examples of current product lines for such manufacturing equipment include the TurboDisc®, MaxBright®, the EPIK® families of MOCVD systems, and the PROPEL® Power GaN MOCVD system, all manufactured by Veeco Instruments Inc. of Plainview, N.Y.

During epitaxial layer growth, a number of process parameters are controlled, such as temperature, pressure, and gas flow rate, to achieve desired quality in the epitaxial layer. Different layers are grown using different materials and process parameters. For example devices formed from compound semiconductor such as III-V semiconductors typically are formed by growing a series of distinct layers. In this process, the wafers are exposed to a combination of gases, typically including a metal organic compound as a source of group III metal, and also including a source of group V element which flow over the surface of the wafer while the wafer is maintained at an elevated temperature. Generally the metal organic compound and group V source are combined with a carrier gas which does not participate appreciably in the reaction, for example, nitrogen or hydrogen. One example of a III-V semiconductor is gallium nitride, which can be formed by reaction of organo-gallium compounds and ammonia on a substrate having a suitable crystal lattice spacing, for example a sapphire or silicon wafer. The wafer is usually maintained at a temperature on the order of 700-1200° C. during the deposition of the gallium nitride and/or related compounds. Another example of an III-V semiconductors indium phosphide (InP), which can be formed by reaction of indium and phosphine or aluminum gallium arsenide (AlGa₁₋ₓAsₓ), which can be formed by the reaction of aluminum, gallium and arsine, the reaction of the compounds forming a semiconductor layer on a suitable substrate.

In general, III V compounds can have the general formula In_{X}Ga_{Y}Al_{Z}N_{A}As_{B}P_{C}Sb_{D}, where X+Y+Z equals approximately one, A+B+C+D equals approximately one, and each of X, Y, Z, A, B, C, and D can be between zero and one. In some instances, bismuth may be used in place of some or all of the other Group III metals. Suitable substrate can be a metal, semiconductor, or an insulating substrate and can include sapphire, aluminum oxide, silicon (Si), silicon carbide (SiC), gallium arsenide (GaAs), indium phosphide (InP), indium arsenide (InAs), gallium phosphide (GaP), aluminum nitride (AlN), silicon dioxide (SiO2), and the like.

Another type of CVD process involves the growth of silicon carbide layers on substrates to form power electronic devices. Silicon carbide layers are grown using silanes and hydrocarbons as the reactive species with hydrogen as a carrier gas. The wafer is usually maintained at a temperature on the order of 800-2000° C. during deposition.

In a CVD process chamber, one or more semiconductor wafers are positioned within a tray, commonly referred to as a wafer carrier, so that the top surface of each wafer is exposed, thereby providing a uniform exposure of the top surface of the wafer to the atmosphere within the reactor chamber for the deposition of semiconductor materials. The wafer carrier is commonly rotated at a rotation speed on the order from about 100 to 1500 RPM or higher. The wafer carriers are typically machined out of a highly thermally conductive material such as graphite, and are often coated with a protective layer of material such as silicon carbide. Each wafer carrier has a set of circular indentations, or pockets, and its top surface in which the individual wafers are placed. Some examples of pertinent technology are described in U.S. Patent Application Publication Nos. 2007/0186853 and 2012/0040097, and U.S. Pat. Nos. 6,492,625; 6,506,252; 6,902,623; 8,021,487; and 8,092,599, the disclosures of which are incorporated by reference herein. Other wafer carriers have a single pocket in which a single wafer is placed.

In some cases, the wafer carrier is supported on a spindle within the reactor chamber so that the top surface of the wafer carrier having the exposed surfaces of the wafers faces upwardly toward a gas distribution device. While the spindle is rotated, the gas is directed downwardly onto the top surface of the wafer carrier and flows across the top surface toward the periphery of the wafer carrier. The used gas can be evacuated from the reaction chamber through ports disposed below the wafer carrier. The wafer carrier can be maintained at the desired elevated temperature by heating elements, typically electric resistive heating elements disposed below the bottom surface of the wafer carrier. These heating elements are maintained at a temperature above the desired temperature of the wafer surfaces, where as the gas distribution device typically is maintained at a temperature well below the desired reaction temperature so as to prevent premature reaction of the gases. Therefore, heat is transferred from the heating elements to the bottom surface of the wafer carrier and flows upwardly through the wafer carrier to the one or more wafers.

In some cases, the wafer carrier can be supported and rotated by a rotational system that does not require a spindle. Such rotation system is described in U.S. Patent Application Publication No. 2015/0075431, the contents of which are hereby incorporated by reference herein. In yet other cases, the wafer carrier can be placed facedown (inverted) in the reaction chamber and the gas injectors are mounted below the wafer carrier such that the gas mixture flows upwardly towards the one or more wafers. Examples of such inverted gas injection systems are described in U.S. Patent Application Publication Nos. 2004/0060518 and 2004/0175939, and U.S. Pat. No. 8,133,322, the contents of which are hereby incorporated by reference herein.

In a CVD process, the wafers must be individually aligned and loaded into the wafer carriers. The wafer carriers must then be carefully placed within the reaction chambers. When a chemical reaction is complete, the wafer carriers must be carefully removed from the reaction chambers. The reaction chamber must then be loaded with another wafer carrier for processing. Such handling of the wafers and wafer carrier can add a significant amount of time to the overall MOCVD process. Additionally, requiring an operator to place his or her hands within a reaction chamber can present a risk, particularly given the high temperature at which the reaction chamber normally operates.

Accordingly, the applicants of the present disclosure have identified a need for a certain degree of automation for the purpose of reducing the processing time while maintaining quality standards required in the production of high-performance semiconductor devices. Moreover, the applicants of the present disclosure have identified a need for a chemical vapor deposition system having multiple chambers for the purpose of reducing processing time.

### SUMMARY OF THE DISCLOSURE

Embodiments of the present disclosure meet the need of a chemical vapor deposition system having a plurality of reaction chambers to operate independently in the growth of epitaxial layers on wafers within each of the reaction chambers for the purpose of reducing processing time while maintaining quality.

In one embodiment of the disclosure, the chemical vapor deposition system includes an automated front-end interface, a first load lock, a second load lock, and a vacuum transfer module. The automated front-end interface can have a first output and a second output, and can include a process tray housing configured to house two or more process trays, a wafer cassette configured to house two or more wafers, an aligner configured to align a first wafer on a first process tray in the second wafer on a second process tray, and an interface robotic arm configured to transfer: (i) the first wafer and the first process tray to the aligner for alignment as the first wafer on the first process tray, (ii) the second wafer and the second process tray to the aligner for alignment as the second wafer on the second process tray, (iii) the aligned first wafer and process tray to the first output, and (iv) the aligned second wafer and process tray to the second output.

The first load lock can include a chamber capable of maintaining a controllable environment. The first load lock can have a first door and a second door, wherein the first door is in communication with the first output of the automated front-end interface. In one embodiment, the first load lock chamber can be configured to receive the aligned first wafer and process tray from the first output through the first door.

The second load lock can include a chamber capable of maintaining a controllable environment. The second load lock can have a first door and a second door, wherein the first door is in communication with the second output of the automated front-end interface. In one embodiment, the second load lock is configured to receive the aligned second wafer and process tray from the second output through the first door.

The vacuum transfer module can be in communication with the second doors of the first and second load lock chambers. The vacuum transfer module can have a dual bladed robotic arm configured to manipulate the aligned first wafer and process tray and the aligned second wafer and process tray from the respective first and second load lock chambers to one or more reaction chamber pairs. The one or more reaction chamber pairs can be in communication with the vacuum transfer module.

In another embodiment of the disclosure, the chemical vapor deposition system can have an automated front-end interface having a first output and a second output. The automated front-end interface can include a process tray, a wafer cassette, an aligner, and interface robotic arm, a load lock, and a vacuum transfer module.

The process tray housing can be configured to house two or more process trays. The wafer cassette can be configured to house two or more wafers. The aligner can be configured to align a first wafer on a first process tray and a second wafer on a second process tray. The interface robotic arm can be configured to transfer wafers and process trays to the aligner, the aligned first wafer and process tray to the first output, and the aligned second wafer and process tray to the second output.

The load lock chamber can be capable of maintaining a controlled environment and which is in communication with the automated front-end interface having a first door in communication with the first output, a second door in communication with the second output, a third door opposite the first door, and a fourth door opposite the second door. The load lock chamber can be configured to receive the first aligned wafer and process tray from the first output through the first door and the aligned second wafer and process tray from the second output through the second door. The load lock chamber can include one or more shelves.

The vacuum transfer module can be in communication with the third and fourth doors of the load lock chamber. The vacuum transfer module can have a dual bladed robotic arm configured to manipulate the aligned first wafer and process tray and the aligned second wafer and process tray from the load lock chamber to one or more reaction chamber pairs which are in communication with the vacuum transfer module.

In another embodiment of the disclosure, the chemical vapor deposition system can include an automated front-end interface, a load lock chamber, and a vacuum transfer module. The automated front-end interface can include a first output and a second output, including a process tray housing, a wafer cassette, an aligner, and an interface robotic arm. The process tray housing can be configured to house two or more process trays. The wafer cassette can be configured to house two or more wafers. The aligner can be configured to align a first wafer on a first process tray and a second wafer on a second process tray. The interface robotic arm can be configured to (i) transfer wafers and process trays to the aligner, (ii) transfer the aligned first wafer and process tray to the first output, and (iii) transfer the aligned second wafer and process tray to the second output.

The load lock chamber can be capable of maintaining a controlled environment and which is in communication with the automated front-end interface having a first chamber, a second chamber, a first door in communication with the first output and the second output, the first chamber being aligned with the first output and the second chamber being aligned with the second output, and a second door opposite the first door, wherein the load lock chamber is configured to receive the aligned first wafer and process tray from the first output and the aligned second wafer and process tray from the second output through the first door into the respective first and second chambers. The load lock chamber can include one or more shelves.

The vacuum transfer module can be in communication with the second door of the load lock chamber. The vacuum transfer module can have a dual bladed robotic arm configured to manipulate the aligned first wafer and process tray and the aligned second wafer and process tray from the respective first and second chambers to one or more reaction chamber pairs which are in communication with the vacuum transfer module.

In another embodiment of the disclosure, the chemical vapor deposition system can include a front-end interface, a load lock chamber and a vacuum transfer module. The front-end interface can have a first output and a second output. The first output can be configured to provide in series, a first process tray containing a wafer and a third process tray containing a wafer. The second output can be configured to provide in series a second process tray containing a wafer and a fourth process tray containing a wafer.

The load lock chamber can be capable of maintaining a controlled environment and which is in communication with the front and interface having a first chamber, a second chamber, a first door in communication with the first output, the first chamber being aligned with the first output and the second chamber being aligned with the second output, and a second door opposite the first door, wherein the load lock chamber is configured to receive in series the first process tray containing the wafer and the third process tray containing the wafer from the first output and the second process tray containing the wafer and the fourth process tray containing the wafer from the second output through the first door into the respective first and second chambers. The load lock chamber can include one or more shelves.

The vacuum transfer module can be in communication with the second door of the load lock chamber. The vacuum transfer module can have a dual bladed robotic arm configured to manipulate the first process tray containing the wafer and the second process tray containing the wafer from their respective first and second chambers to a first reaction chamber pair which are in communication with the vacuum transfer module and the third process tray containing the wafer and fourth process tray containing the wafer from the respective first and second chambers to a second reaction chamber pair which can be in communication with the vacuum transfer module.

In another embodiment of the disclosure, the chemical vapor deposition system can include a front end interface, a load lock chamber and a vacuum transfer module. The front-end interface can have a first output and a second output. The first output can be configured to provide in series a first process tray containing a wafer, a third process tray containing a wafer, and a fifth process tray containing a wafer. The second output can be configured to provide in series a second process tray containing a wafer, a fourth process tray containing a wafer, and a six process tray containing a wafer.

The load lock chamber can be capable of maintaining a controlled environment and which is in communication with the front and interface having a first chamber, a second chamber, a first door in communication with the first output and the second output. The first chamber can be aligned with the first output and the second chamber can be aligned with the second output. A second door can be opposite the first door, wherein the load lock chamber is configured to receive in series the first process tray containing the wafer, the third process tray containing the wafer, and the fifth process tray containing the wafer from the first output and the second process tray containing the wafer, the fourth process tray containing the wafer and the sixth process tray containing the wafer from the second output through the first door into the respective first and second chambers. The load lock chamber can include one or more shelves.

The vacuum transfer module can be in communication with the second door of the load lock chamber. The vacuum transfer module can have a dual bladed robotic arm configured to manipulate the first process tray containing the wafer and the second process tray containing the wafer from the respective first and second chambers to a first reaction chamber pair which are in communication with the vacuum transfer module, the third process tray containing the wafer and the fourth process tray containing the wafer from the respective first and second chambers to a second reaction chamber pair which are in communication with the vacuum transfer module, and the fifth process tray containing the wafer and the six process tray containing the wafer from the respective first and second chambers to a third reaction chamber pair which are in communication with the vacuum transfer module.

In another embodiment of the disclosure, the chemical vapor deposition can include a front-end interface, a load lock chamber, a vacuum transfer module, and one or more reaction chamber pairs. The front-end interface can have a first output and a second output. The first output can be configured to provide a first process tray containing a wafer. The second output can be configured to provide a second process tray containing a wafer.

The load lock chamber can be capable of maintaining a controlled environment and which is in communication with the front-end interface having a first chamber, a second chamber, a first door in communication with the first output and the second output, the first chamber being aligned with the first output and the second chamber being aligned with the second output, and a second door opposite the first door, wherein the load lock chamber is configured to receive the first process tray containing the wafer from the first output and the second process tray containing the wafer from the second output through the first door into the respective first and second chambers. The load lock chamber can include one or more shelves.

The vacuum transfer module can be in communication with the second door of the load lock chamber. The vacuum transfer module can have a dual bladed robotic arm configured to manipulate the first process tray containing the wafer and the second process tray containing the wafer from the respective first and second chambers.

The one or more reaction chamber pairs can be in communication with the vacuum transfer module. The one or more reaction chambers can be capable of receiving the first process tray containing the wafer and the second process tray containing the wafer, wherein the one or more reaction chambers can be configured to perform a process selected from metal organic chemical vapor deposition, chemical vapor deposition, physical vapor deposition, plasma enhanced vapor deposition, plasma enhanced chemical vapor deposition, atomic layer deposition, plasma enhanced atomic layer deposition, and atomic layer epitaxy.

In another embodiment of the disclosure, the chemical vapor deposition can include a front end interface, a load lock chamber, a vacuum transfer module, and one or more reaction chamber pairs. The front-end interface can have a first output and a second output. The first output can be configured to provide a first process tray containing a wafer. The second output can be configured to provide a second process tray containing a wafer.

The load lock chamber can be capable of maintaining a controlled environment and which is in communication with the front and interface having a first chamber, a second chamber, a first door being in communication with the first output and the second output, a first chamber being aligned with the first output and the second chamber being aligned with the second output, and a second door opposite the first door, wherein the load lock chamber is configured to receive the first process tray containing the wafer from the first output and a second process tray containing the wafer from the second output through the first door into the respective first and second chambers. The load lock chamber can include one or more shelves.

The vacuum transfer module can be in communication with the second door of the load lock chamber. The vacuum transfer module can have a dual bladed robotic arm configured to manipulate the first process tray containing the wafer and the second process tray containing the wafer from the respective first and second chambers.

The one or more reaction chamber pairs can be in communication with the vacuum transfer module, and can be capable of receiving the first process tray containing the wafer and the second process tray containing the wafer, wherein the one or more reaction chambers are provided with one or more metrology tools.

In some of the foregoing chemical vapor deposition system embodiments, the chemical vapor deposition system can include one pair of reaction chambers which operate independently (two independently operating reaction chambers). In some of the foregoing chemical vapor deposition system embodiments, the chemical vapor deposition can include two pairs of reaction chambers which operate independently (four independently operating reaction chambers). In some of the foregoing chemical vapor deposition system embodiments, the chemical vapor deposition system can include three pairs of reaction chambers which operate independently (six independently operating reaction chambers).

In some of the foregoing chemical vapor deposition system embodiments, the one or more reaction chambers can perform a process selected from metal organic chemical vapor deposition, chemical vapor deposition, physical vapor deposition, plasma enhanced physical vapor deposition, plasma enhanced chemical vapor deposition, atomic layer deposition, plasma enhanced atomic layer deposition, and atomic layer epitaxy. In some of the foregoing chemical vapor deposition system embodiments, the one or more reaction chambers can include one or more metrology tools.

In some of the foregoing chemical vapor deposition system embodiments, the chemical vapor deposition system can include a source delivery assembly positioned adjacent to at least one of the plurality of reaction chambers. In some of the foregoing chemical vapor deposition system embodiments, the source delivery assembly can be configured to provide a carrier gas, one or more reaction gases, a cooling system, and ventilation system for two reaction chambers (one pair of reaction chambers).

In some of the foregoing chemical vapor deposition system embodiments, the load lock can comprise one or more chambers. In some of the foregoing chemical vapor deposition system embodiments, the load lock, including the first and/or second load lock can include at least one shelf, thereby dividing load lock into two or more compartments. In some of the foregoing chemical vapor deposition system embodiments, the one or more compartments and/or chambers can be independently controlled environmental chambers and/or compartments. In some of the foregoing chemical vapor deposition system embodiments, the controllable environment within the two or more compartments can be configured to be independently regulated. In some of the foregoing chemical vapor deposition system embodiments, the controllable environment within two or more compartments is configured to be the same. In some of the foregoing chemical vapor deposition system embodiments, the controllable environment within the two or more compartments is configured to establish a negative pressure. In some of the foregoing chemical vapor deposition system embodiments, the controllable environment within the two or more compartments is configured to establish an atmospheric pressure environment In some of the foregoing chemical vapor deposition system embodiments, the controllable environment within the two or more compartments is configured to maintain an inert gas environment. In some of the foregoing chemical vapor deposition system embodiments, the controlled environment within the two or more compartments is configured to maintain a controlled humidity environment. In some of the foregoing chemical vapor deposition system embodiments, the controllable environment within two or more compartments is configured to maintain a low particle containing environment. In some of the foregoing chemical vapor deposition system embodiments, the controllable environment within two or more compartments is configured to maintain a controlled temperature environment.

In some of the foregoing chemical vapor deposition system embodiments, the interface robotic arm can transfer at least any two of the first wafer, first process tray, second wafer, and second wafer tray simultaneously. In some of the foregoing chemical vapor deposition system embodiments, the interface robotic arm can transfer the aligned first wafer and process tray and the aligned second wafer and process tray to the respective first output and second output simultaneously. In some of the foregoing chemical vapor deposition system embodiments, the automated front-end interface can include two interface robotic arms, wherein the two interface robotic arms can be configured to operate independently and simultaneously of one another.

In some of the foregoing chemical vapor deposition system embodiments, the vacuum transfer module can include a plurality of doors configured to selectively provide access between an interior chamber of the vacuum transfer module and a plurality of reaction chambers. In some of the foregoing chemical vapor deposition system embodiments, the vacuum transfer module can include one or more shelves.

In some of the foregoing chemical vapor deposition system embodiments, each process tray can be configured to receive a single wafer with a diameter of between six and eight inches. In some of the foregoing chemical vapor deposition system embodiments, each process tray can be configured to receive a single wafer with a diameter of between eight and ten inches. In some of the foregoing chemical vapor deposition system embodiments, each process tray can be configured to receive a single wafer with a diameter of between ten and twelve inches.

In another embodiment of the disclosure, a method for preparing a plurality of wafers for growth of epitaxial layers within a plurality of reaction chambers is disclosed. In one embodiment, the method can include the steps of:

providing an automated front-end interface configured with (i) a wafer cassette configured to house two or more wafers, and (ii) a process tray housing configured to house two or more process trays;

aligning a first wafer from the wafer cassette on a first process tray from the process tray housing via the aligner;

transferring the aligned first wafer and first process tray from the aligner into a first load lock chamber via the interface robotic arm;

aligning a second wafer from the wafer cassette on a second process tray from the process tray housing via the aligner; and

transferring the aligned second wafer and second process tray from the aligner into a second load lock chamber via the interface robotic arm

In some embodiments, the method further includes the steps of:

sealing the first load lock chamber and the second load lock chamber and controlling the environment therein,wherein the environment is controlled by at least one of establishing a negative pressure environment, maintaining an inert gas environment, maintaining a controlled humidity environment, and maintaining a low particle containing environment;

opening respective doors on the first load lock and the second load lock, thereby putting the first load lock chamber and the second load lock chamber in fluid communication with a vacuum transfer module;

transferring simultaneously the aligned first wafer and first process tray from the first load lock chamber through the vacuum transfer module and into a first reaction chamber and the aligned second wafer and second process tray from the second load lock chamber through the vacuum transfer module and into a second reaction chamber via a dual bladed robotic arm;

processing the aligned first wafer and first process tray in the first reaction chamber and processing the aligned second wafer and second process tray and the second reaction chamber;

transferring simultaneously the processed first wafer and first process tray from the first reaction chamber to the first load lock chamber and the second process tray and the second process tray from the second reaction chamber to the second load lock chamber via the dual bladed robotic arm.

In another embodiment of the disclosure, a method for preparing a plurality of wafers for growth of epitaxial layers within a plurality of reaction chambers is disclosed. In another embodiment, the method can include the steps of:

providing an automated front-end interface configured with (i) a wafer cassette configured to house two or more wafers, (ii) a process tray housing configured to house two or more process trays, and (iii) an interface robotic arm;

providing a vacuum transfer chamber which is in communication with the automated front-end interface;

transferring a first wafer from the wafer cassette to a wafer aligner via the interface robotic arm, the wafer aligner aligning the wafer;

transferring a first process tray from the process tray housing to a process tray aligner via the interface robotic arm, the process tray aligner aligning the process tray;

transferring the first aligned wafer from the wafer aligner to the aligned process tray for alignment of the first wafer on the first process tray;

transferring the aligned first wafer and first process tray from the aligner into a load lock chamber via the interface robotic arm;

transferring a second wafer from the wafer cassette to a wafer aligner via an interface robotic arm, the wafer aligner aligning the wafer;

transferring a second process tray from the process tray housing to a process tray aligner via the interface robotic arm, the process tray aligner aligning the process tray;

transferring the second aligned wafer from the wafer aligner to the aligned process tray for alignment of the second wafer on the second process tray;

transferring the aligned second wafer and second process tray from the aligner into the load lock chamber via the interface robotic arm; and

transferring the aligned first wafer and first process tray from the load lock chamber through the vacuum transfer module and into a first reaction chamber and the aligned second wafer and second process tray from the load lock chamber through the vacuum transfer module and into a second reaction chamber simultaneously via a dual bladed robotic arm.

In another embodiment of the disclosure, a method for preparing a plurality of wafers for growth of epitaxial layers within a plurality of reaction chambers is disclosed. In another embodiment, the method can include the steps of:

providing an automated front-end interface configured with (i) a wafer cassette configured to house two or more wafers and (ii) a process tray housing configured to house two or more process trays;

providing a vacuum transfer chamber which is in communication with the automated front-end interface;

transferring a first wafer from the wafer cassette to a wafer aligner via the interface robotic arm, the wafer aligner aligning the wafer;

transferring a first process tray from the process tray housing to a process tray aligner via the interface robotic arm, the process tray aligner aligning the process tray;

transferring the first aligned wafer from the wafer aligner to the aligned process tray for alignment of the first wafer on the first process tray;

transferring the aligned first wafer and first process tray from the aligner into a load lock chamber via the interface robotic arm;

transferring a second wafer from the wafer cassette to a wafer aligner via an interface robotic arm, the wafer aligner aligning the wafer;

transferring a second process tray from the process tray housing to a process tray aligner via the interface robotic arm, the process tray aligner aligning the process tray;

transferring the second aligned wafer from the wafer aligner to the aligned process tray for alignment of the second wafer on the second process tray;

transferring the aligned second wafer and second process tray from the aligner into the load lock chamber via the interface robotic arm.

The summary above is not intended to describe each illustrated embodiment or every implementation of the present disclosure. The figures and the detailed description that follow more particularly exemplify these embodiments.

### BRIEF DESCRIPTION OF THE DRAWINGS

The disclosure can be more completely understood in consideration of the following detailed description of various embodiments of the disclosure, in connection with the accompanying drawings, in which:

FIG. 1 is a schematic view depicting a chemical vapor deposition system having six reaction chambers (three pairs of reaction chambers) in accordance with an embodiment of the disclosure.

FIG. 2 is a schematic view depicting a chemical vapor deposition system having four reaction chambers (two pairs of reaction chambers) in accordance with an embodiment of the disclosure.

FIG. 3 is a schematic view depicting a chemical vapor deposition system having two reaction chambers (one pair of reaction chambers) in accordance with an embodiment of the disclosure.

FIG. 4A is an isometric view of a first and second load lock in accordance with an embodiment of the disclosure.

FIG. 4B is an isometric view of a first and second load lock in accordance with an embodiment of the disclosure.

FIG. 5 is a plan view of a reaction chamber having a spindle including a fitting adapted to releasably engage a process tray in accordance with an embodiment of the disclosure.

FIG. 6 is a plan view of a reaction chamber having a rotating dielectric support in accordance with an embodiment of the disclosure.

While embodiments of the disclosure are amenable to various modifications and alternative forms, specifics thereof are shown by way of example in the drawings and will be described in detail. It should be understood, however, that the intention is not to limit the disclosure to the particular embodiments described. On the contrary, the intention is to cover all modifications, equivalents, and alternatives falling within the spirit and scope of the disclosure as defined by the appended claims.

### DETAILED DESCRIPTION

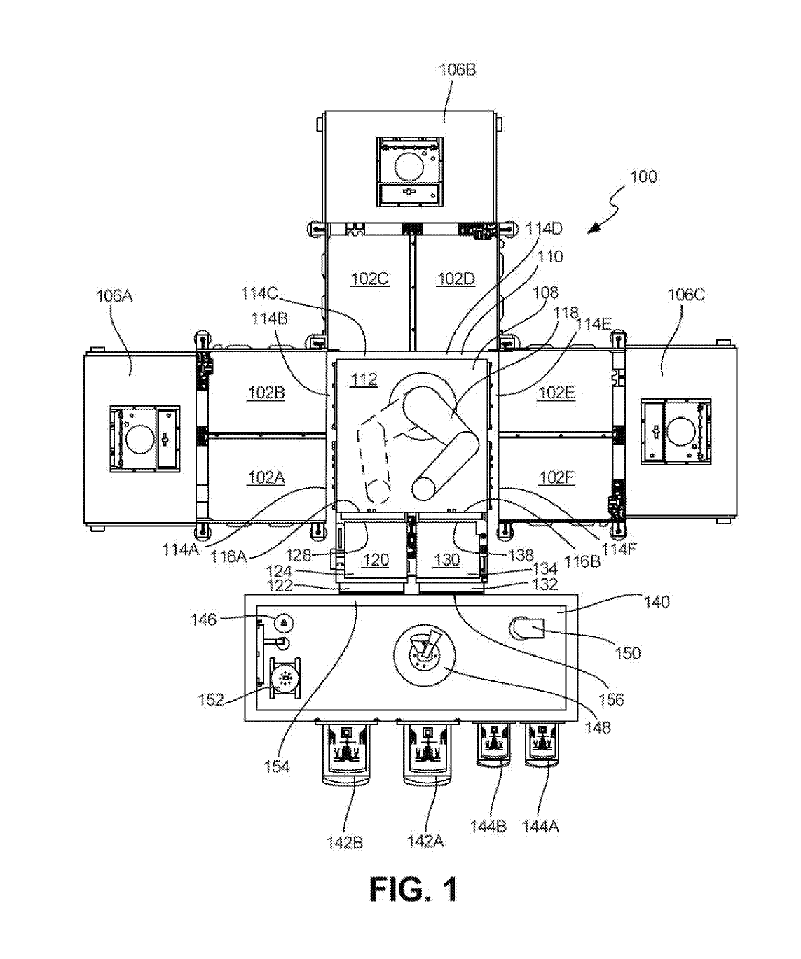

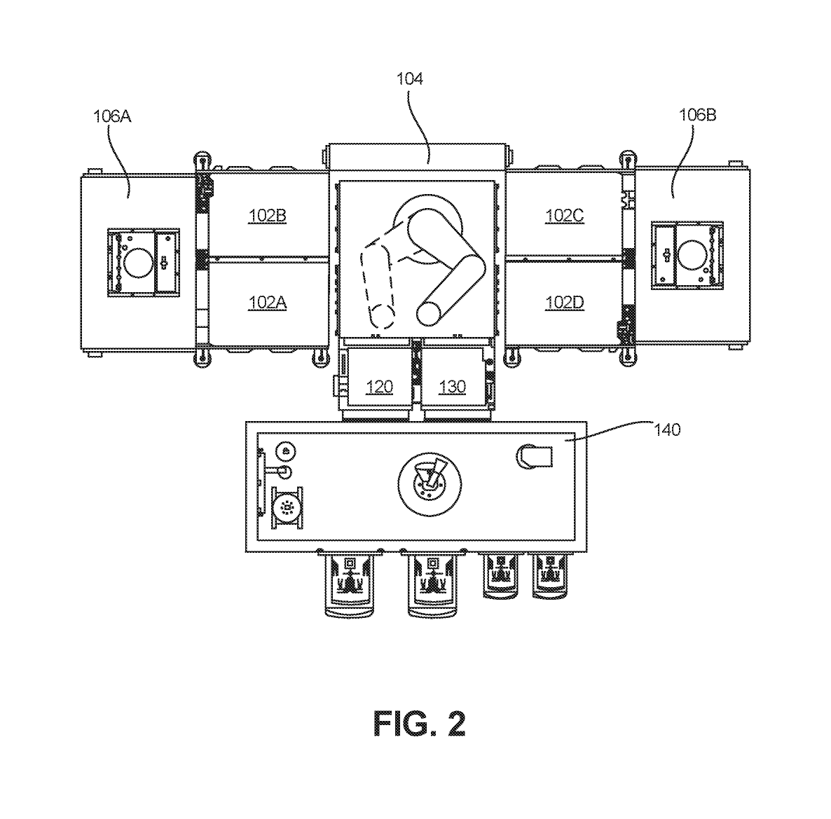

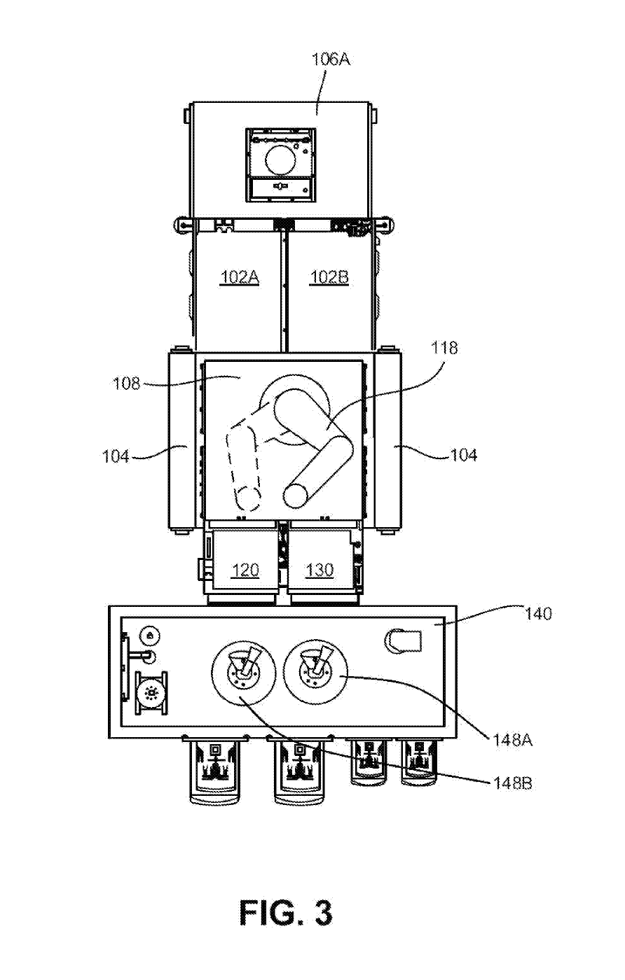

Referring to FIG. 1, a chemical vapor deposition system 100 is depicted in accordance with an embodiment of the disclosure. Chemical vapor deposition system 100 can include a plurality of reaction chambers 102A-F. In one embodiment, reaction chambers 102A-F can be configured to operate independently, as well as simultaneously, in the growth of epitaxial layers on wafers within each of the reaction chambers 102A-F for the purpose of reducing wafer processing time while maintaining the quality standards required to produce high-performance semi conductor devices. For example, in one embodiment the chemical vapor deposition system 100 can include three pairs of reaction chambers (six reaction chambers 102A-F). In other embodiments, the system 100 can include another number of reaction chambers. For example, the system 100 can include two pairs of reaction chambers (four reaction chambers 102A-D) (as depicted in FIG. 2), or one pair of reaction chambers (two reaction chambers 102A-B) (as depicted in FIG. 3).

In some embodiments, the system 100 can be modular, such that an even number of reaction chambers 102 can be added as needed. Each of the reaction chambers 102A-F can be isolated from each other. In cases where less than the full number of reaction chambers 102 are installed on the system 100, a buffer 104 can be added in the place of one or more reaction chamber pairs 102A/102B, for example. In one embodiment, buffer 104 can include a chamber maintained at a negative pressure substantially equal to the pressure of the plurality of reaction chambers 102 and/or a centralized vacuum transfer module 108. Buffer 104 can include one or more pedestals on which one or more process trays can be positioned. The pedestals can have a cooling function.

In some embodiments, reaction chambers 102A-F can be operably coupled to one or more source delivery assemblies 106A-C. Each source delivery assembly 106A-C can include one or more reaction gases, cooling systems and ventilation systems. In one embodiment, multiple reaction chambers, for example reaction chambers 102A-B can be coupled to a single source delivery assembly 106A, such that the source delivery assembly 106A provides the one or more reaction gases, cooling systems and ventilation systems required of reaction chambers 102A-B.

The plurality of reaction chambers 102A-F can be operably coupled together by a vacuum transfer module 108. The vacuum transfer module 108 can include an interior wall 110 defining a chamber 112. Interior wall 110 can include a plurality of doors 114A-F configured to selectively provide access between the chamber 112 of the vacuum transfer module 108, and the interior of the one or more of the reaction chambers 102A-F. The plurality of doors 114A-D can be configured to open when access between the chamber 112 and the interior of the one or more reaction chamber pairs 102A/102B, 102C/102D, and/or 102E/102F as desired, for example when the one or more reaction chamber pairs 102A/102B, 102C/102D, and/or 102E/102F is being loaded or unloaded. A plurality of doors 114A-D can be configured to close access between the chamber 112 and the interior of the one or more reaction chamber pairs 102A/102B, 102C/102D, and/or 102E/102F when access is no longer needed, for example during the chemical reaction process in the one or more reaction chamber pairs 102A/102B, 102C/102D, and/or 102E/102F.

In one embodiment, the plurality of doors 114A-F are sliding or rolling members configured to close an orifice defined in interior wall 110. Interior wall 110 of vacuum transfer module 108 can further include a first load lock access 116A and a second load lock access 116B, configured to enable access to within chamber 112 from outside of the vacuum transfer module 108. In other embodiments, interior wall 110 can include a plurality of load lock accesses, configured to enable access to within chamber 112 from outside of the vacuum transfer module 108.

Vacuum transfer module 108 can include a transfer module robotic arm 118. In one embodiment, transfer module robotic arm 118 can include a pivotable shoulder, a first arm segment, a pivotable elbow, a second arm segment, a pivotable wrist, and one or more grips. In one embodiment, transfer module robotic arm 118 is dual bladed, meaning that it can additionally include at least one of a second pivotable shoulder, a second first arm segment, a second pivotable elbow, a second second arm segment, a second pivotable wrist, and a second one or more grips. Transfer module robotic arm 118 can be substantially centrally located within chamber 112, and can be configured to manipulate process trays and wafers within chamber 112, as well as through doors 114A-F and load lock access doors 116A-B.

In one embodiment, a first load lock 120 can be operably coupled to the vacuum transfer module 108 at the load lock access door 116A, and a second load lock 130 can be operably coupled to the vacuum transfer module 108 at the load lock access door 116B. The first load lock 120 and the second load lock 130 can each include a first door 122, 132, a chamber 124, 134 and a second door 128, 138. The first and second load locks 120, 130 can each be configured to receive process trays and wafers through their respective first doors 122, 132 and into chambers 124, 134. The first doors 122, 132 can be configured to close so as to provide a controlled environment within chamber 124, 134. For example, pressure regulators (not shown) can be connected to chambers 124, 134 to create a pressure sealed environment. The pressure regulators can then evacuate gas within chamber 124, 134 to create a negative pressure relative to the atmospheric pressure. The second door 128, 138 can then be open to selectively provide access to the chamber 112 of the vacuum transfer module 108, thereby permitting access to the vacuum transfer module 108 from an area outside of the interior wall 110, while maintaining a constant pressure within the vacuum transfer module 108. The controllable environment can also include the control of at least one or more of the atmospheric environment, inert gas environment, controlled humidity environment, low particle containing environment, temperature environment, and the like.

Likewise, the first and second load locks 120, 130 can be configured to receive process trays and wafers through the second door 128, 138 and into chamber 124, 134. Pressure regulators can then partially fill the chamber 124, 134 with gas to substantially equalize the pressure within chamber 124, 134 to the atmospheric pressure. The first door 122, 132 can then be opened to selectively provide access from within chamber 124, 134, thereby permitting access from within the vacuum transfer module 108 to an area outside of the interior wall 110, while maintaining a constant pressure within the vacuum transfer module 108.

In one embodiment, each of the first and second load locks 120, 130 can include at least one shelf, thereby dividing the first and second load locks 120, 130 into two or more compartments. In one embodiment, the pressure within the two or more compartments is configured to be independently regulated. In another embodiment, one compartment in first load lock 120, for example, a top compartment thereof, and one compartment in second load lock 130, for example, a top compartment thereof, is configured such that the pressure and atmosphere can be regulated such that the pressure and/or atmosphere are the same during unloading and loading sequences. In other embodiments, the environment within the two or more compartments can include the control of at least one or more of a negative pressure environment, atmospheric environment, inert gas environment, controlled humidity environment, low particle containing environment, temperature environment (including heating and/or cooling), and the like.

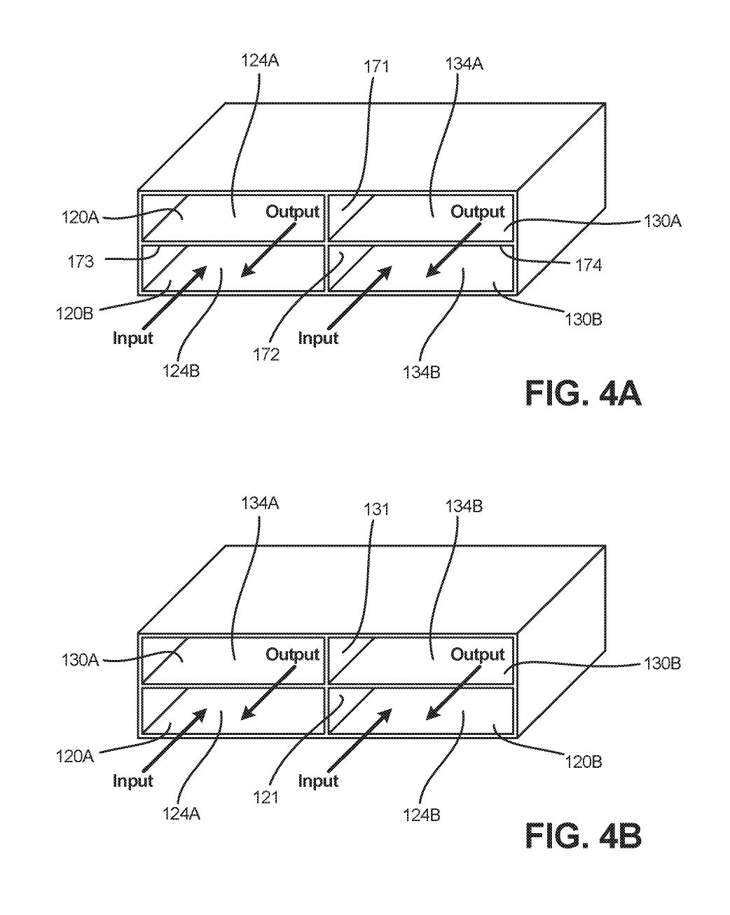

Referring to FIG. 4A, one configuration for the first and second load locks 120, 130 is depicted. In this embodiment, second load lock 130 can be positioned adjacent to the first load lock 120, separated by a wall (wall portion 171 on the top and wall portion 172 on the bottom). A partition 173 can be used to divide the first load lock 120 into two separate compartments or chambers 124A and 124B. A partition 174 can be used to divide the second load lock 130 into two separate compartments or chambers 134A and 134B. In some embodiments, there are separate doors on all of the compartments, such that the respective chambers 124A/B and 134A/B can be independently accessed and sealed. In one embodiment, the pressure within the two or more compartments is configured to be independently regulated. In another embodiment, the pressure within two or more compartments can be regulated together, for example, chambers 124A and 124B, or 134A and 134B.

Referring to FIG. 4B, another configuration for the first and second load locks 120, 130 is depicted. In this embodiment, second load lock 130 can be positioned on top of the first load lock 120. A partition 121 can be used to divide the first load lock 120 into two separate compartments or chambers 120A and 120B. A partition 131 can be used to divide the second load lock 130 into two separate compartments or chambers 130A and 130B. In some embodiments, there are separate doors on all of the compartments, such that the respective chambers 124A/B and 134A/B can be independently accessed and sealed. In one embodiment, the pressure within the two or more compartments is configured to be independently regulated. In another embodiment, the pressure within two or more compartments can be regulated together, for example, chambers 124A and 124B, 134A and 134B. The compartments can also have controllable environments such as atmospheric environment, inert gas environment, controlled humidity environment, low particle containing environment, temperature environment, and the like.

In another embodiment, there can be a single load lock which sits in the space occupied by load locks 120 and 130. The single load lock can have individual chambers having one or more shelves, a first door (which can be a single door or two individual doors) that correlates to first doors 122 and 132, and a second door (which can be a single door or to individual doors) that correlates to second doors 128 than 138. The single load lock can also have one or more pressure regulators similar to those described for load locks 120 and 130. The operation of the first door or the second door of the single load lock can be similar to the operation of the first doors 122 and 132 of load lock 120 and load lock 130 and the second doors 128 and 138 of load lock 120 and load lock 130. The single load lock can also have a controllable environment such as atmospheric environment, inert gas environment, controlled humidity environment, low particle containing environment, temperature environment, and the like.

In embodiments with multiple load lock chambers and/or compartments, certain chambers and/or compartments can be designated to receive unprocessed wafers and process trays, while other chambers and/or compartments can be designated to receive processed wafers and process trays, such that wafers pass-through certain chambers and/or compartments only in a specified direction.

In another embodiment, certain chambers and/or compartments can remain open to the vacuum transfer module 108 at all times, so as to serve as a buffer. In one embodiment, the one or more buffers can be maintained at a negative pressure substantially equal to the pressure of the centralized vacuum transfer module 108, and can include a pedestal on which one or more wafers can be positioned. In one embodiment, the pedestals can have a cooling function to produce a controlled cooling effect on processed wafers positioned thereon. One or more buffers 104 can also be located in one or more of the load locks 120 and 130, in the automated front-end interface 140, or the manual front-end interface.

In one embodiment, each chamber or compartment of load locks 120, 130 can be configured with the pedestal on which aligned wafers and process trays can be positioned. In some embodiments, the pedestals can have a cooling function.

In one embodiment, an automated front-end interface 140 can be operably coupled to at least one of the first load lock 120 or second load lock 130. Automated front-end interface 140 can include one or more process tray housings 142, one or more wafer cassettes 144, an aligner 146, and one or more interface robotic arm 148.

In one embodiment, process tray housing 142A can be configured to house one or more process trays prior to use in the chemical vapor deposition process, while process tray 142B can be configured to house one or more process trays after use in the chemical vapor deposition process. Process tray housings 142 can be configured to be removed and replaced from the automated front-end interface 140 with other process tray housings 142 as needed, for example to replenish the supply of unused process trays, or remove used process trays.

In one embodiment, wafer cassette 144A can be configured to house one or more wafers prior to processing in the chemical vapor deposition process, while wafer cassette 144B can be configured to house one or more wafers after processing in the chemical vapor deposition process. Alternatively, after the chemical vapor deposition process, the process wafers can be placed in their original wafer cassette. Wafer cassettes 144 can be configured to be removed and replaced from the automated front-end interface 140 with other wafer cassettes 144 as needed.

Interface robotic arm 148 can be configured to grasp one or more wafers from the wafer cassette 144 and place it on a wafer aligner 152. In one embodiment, the wafers contain a notch or flattened portion on their outer diameter and the wafer aligner 152 enables the wafer to be rotated until the notch or flattened portion reaches a certain position. Interface robotic arm 148 can be configured to grasp one or more process tray (sometimes referred to as a wafer carrier) from the process tray housing 142 and place it on the process tray aligner 152, so that the process tray can be properly oriented.

Interface robotic arm 148 can be configured to grasp the one or more wafer from the wafer aligner 152 and place it on aligner 146. Interface robotic arm 148 can be configured to grasp the one or more process tray from the process tray aligner 152 and place it on aligner 146. Aligner 146 can be configured to aid in the alignment of the one or more wafer on the one or more process tray.

In some embodiments, interface robotic arm 148 is used to perform at least a portion of the alignment. Interface robotic arm 148 can be configured to grasp the aligned wafer and process tray for transfer through a first output 154 or a second output 156 of the automated front-end interface 140 and into the first or second load lock 120, 130. In one embodiment, multiple interface robotic arms 148A/B (as depicted in FIG. 3) can be configured to grasp the aligned wafers and process trays for independent and/or simultaneous transfer through first and/or second output 154, 156 of the automated front-end interface 140 and into the first and/or second load lock 120, 130. For example, the front-end interface 140 can include two interface robotic arms 148, wherein one interface robotic arm 148A is configured to load and unload a first chamber or set of chambers within a load lock 120, 130 and the second interface robotic arm 148B is configured to load and unload a second chamber set of chambers within a load lock 120, 130.

In one embodiment, first load lock 120 is operably coupled to the first output 154, while the second load lock 130 is operably coupled to the second output 156. In embodiments where the first and/or second load lock 120, 130 is divided into multiple compartments, each compartment can have a separate door in communication with the respective first output 154 and second output 156. Additionally, interface robotic arm 148 can be configured to grasp wafers and process trays for transfer from the first or second load locks 120, 130 into the automated front-end interface 140 through the respective first and second outputs 154, 156.

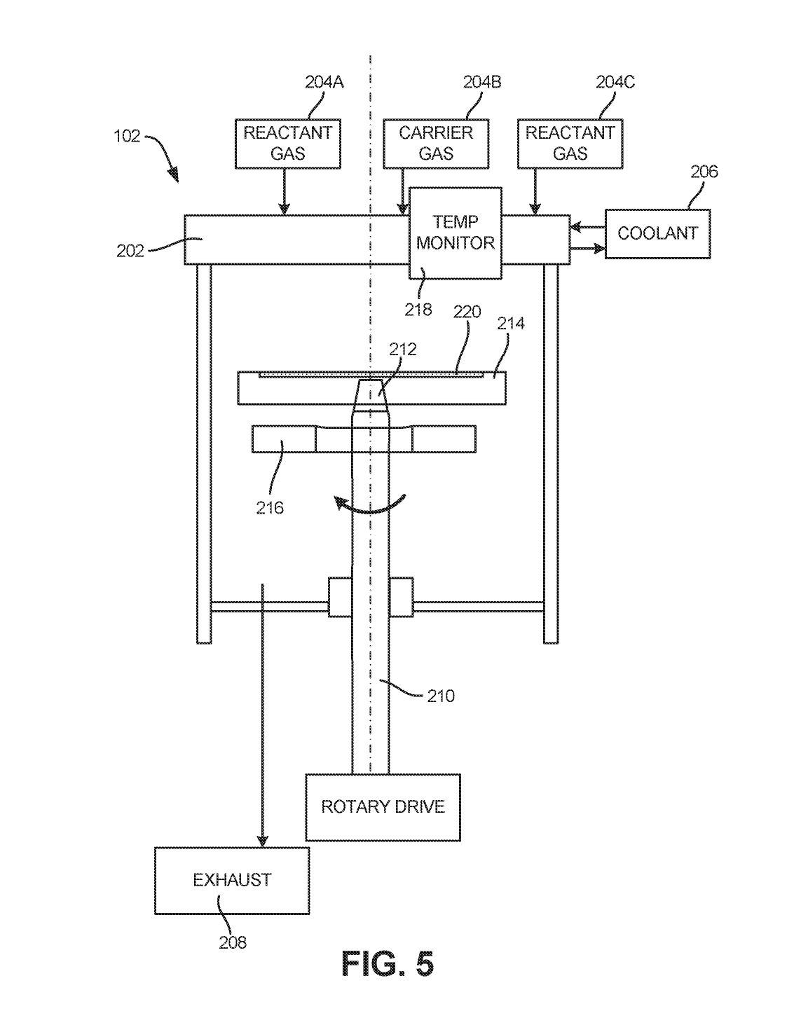

Referring to FIG. 5, an example reaction chamber 102 is depicted in accordance with an embodiment of the disclosure. Reaction chamber 102 defines a process environment space, in which a gas distribution device 202 can be arranged at one end of the environment space. Gas distribution device 202 can be connected to sources 204A-C for supplying process gases to be used in the wafer treatment process, such as a carrier gas and reactant gases such as a metal organic compound and a source of a group V model, all of which can be incorporated into source delivery assembly 106 (as depicted in FIGS. 1-3). The gas distribution device 202 can be arranged to receive the various gases and to direct the flow of the combined process gases. The gas distribution device 202 can also be connected to a coolant system 206 configured to circulate a liquid through the gas distribution device 202 so as to maintain the temperature of the gas distribution device 202 at a desired temperature during operation. A similar coolant arrangement (not shown) can be provided for cooling the walls of the reaction chamber 102.

Reaction chamber 102 can also be provided with an exhaust system 208. Exhaust system 208 can be configured to remove spent gases from the process environment space through one or more ports (not shown) within the process environment space in an area generally distal from the gas distribution device 202.

A spindle 210 can be arranged within the reaction chamber 102 so that the spindle 210 can rotate about a central access. Spindle 210 can include a fitting adapted to releasably engage a process tray 214. A heating element 216 can be mounted within the reaction chamber 102 below the process tray 214. In some embodiments, a temperature monitor 218 is provided to monitor the temperature of the environment space within reaction chamber 102.

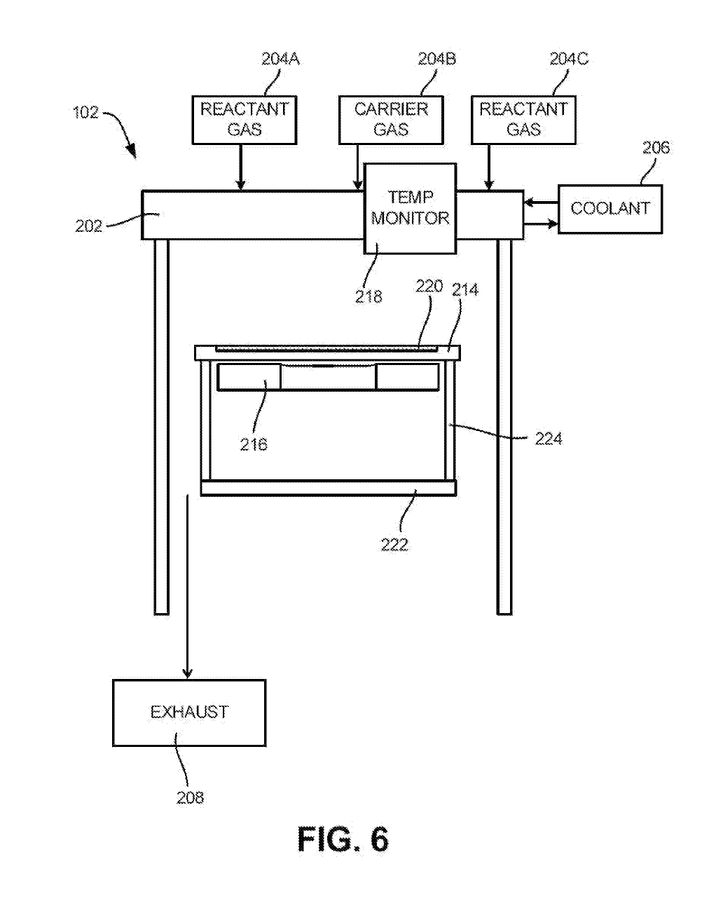

Referring to FIG. 6, another example reaction chamber 102 is depicted in accordance with an embodiment of the disclosure. In this embodiment, a turntable 222 is positioned in a cool region of the reaction chamber 102. The bottom of the turntable 222 can include a bearing or guide wheel system that enables rotation. A rotating dielectric support 224, which can be a hollow cylinder, can be coupled to the top of the turntable 222. A process tray 214 can be positioned on top of the rotating dielectric support 224. The process tray 214 can be mechanically attached to the rotating dielectric support 224, or can be freely positioned on the top surface of the rotating dielectric support 224 and held in position by friction.

Process tray 214, alternatively referred to as a wafer carrier, can have a body substantially in the form of a circular disk symmetrically formed about a central access. The body can include one or more pockets for holding a wafer 220. In some embodiments, the process tray 214 can include a single pocket configured to hold a single wafer 220. For example, in one embodiment, the process tray 214 can be configured to receive a single wafer 220 with a diameter between six and twelve inches.

Single substrate process trays 214 can provide numerous processing advantages. For example, single substrate process trays 214 can provide greater temperature uniformity across the wafer, they can provide higher throughput and greater protection of critical components from reactive process chemistries, they can provide improved gas efficiency, they can allow for fewer points of contact that multi-wafer process trays, they can take shorter time periods to achieve a desired rotation speed, and they can be less expensive to produce than multi-wafer process trays.

In operation, one or more process tray housings 142 and one or more wafer cassettes 144 are loaded onto the automated front-end interface 140. The one or more process tray housings 142A/B and wafer cassettes 144A/B can be loaded by a user, who can then map their various locations. Interface robotic arm 148, which in some embodiments can have an end effector, can transfer one or more wafers 220 from, for example, wafer cassette 144A to the wafer aligner 150. The wafer aligner 150 can be configured to align and temporarily house the wafer 220. Interface robotic arm 148 can additionally transfer one or more process trays 214 from, for example, process tray housing 142A to the process tray aligner 152. The process tray aligner 152 can be configured to align and temporarily house the process tray 214.

Interface robotic arm 148 can remove the wafer 220 from the wafer aligner 154, and transfer the wafer 220 to the aligner 146. In one embodiment, the aligner 146 has a noncontact type end effector and a process tray centering ring. In one embodiment, interface robotic arm 148 can position the wafer 220 in the aligner 146 such that the noncontact type and effector removes the wafer 220 from the end effector of the interface robotic arm 148 and secures the wafer 220 in place. Interface robotic arm 148 can then transfer the process tray 214 from the process tray aligner 152 to aligner 146, where the centering ring can align the process tray 214 with the wafer 220. Interface robotic arm 148 can then transfer the aligned process tray 214 and wafer 220 from aligner 146 through the first output 154 into the first load lock 120. In some embodiments, this process is repeated to align a second wafer 220 on a second process tray 214, which can then be transferred via interface robotic arm 148 through the second output 156 into the second load lock 130.

Once the wafer 220 and process tray 214 are within the respective chambers 124, 134 of the first and second load locks 120, 130, and the interface robotic arm 150 has been retracted out of the chambers 124, 134, the first doors 122, 132 can close, thereby creating an isolated controllable environment, for example, pressure environment, within chambers 124, 134. With both the first doors 122, 132 and the second doors 128, 138 closed, the pressure regulators can evacuate a portion of the gas within the chambers 124, 134 to create a negative pressure substantially equal to the operating pressure within the vacuum transfer module 108. Once the desired pressure within chambers 124, 134 has been established, the second doors 128, 138 can be opened. In one embodiment, the first load lock 120 and the second load lock 130 operate entirely independent of one another. The environments of chambers 124 and 134 can also be controlled through other regulators (not shown) to have an inert environment (for example, nitrogen or argon), low or otherwise controlled humidity, and the like.

Transfer module robotic arm 118 within vacuum transfer module 108 can then grasp the wafer 220 and process tray 214 from the respective first and second load lock chambers 124, 134 and transfer them to, for example, reaction chambers 102A and 102B for processing. In one embodiment, transfer module robotic arm 118 is dual bladed, thereby enabling transfer of two sets of wafers to 220 and process trays 214 independently and simultaneously. Doors 114A and 114B can open and close accordingly to enable the wafers 220 and process trays 214 to pass therethrough and into reaction chambers 102A and 102B.

After the desired processing within reaction chambers 102A and 102B has occurred, the doors 114A and 114B can be opened and the wafers 220 and process trays 214 can be removed from reaction chambers 102A and 102B by transfer module robotic arm 118 and transferred to the first or second load locks 120, 130.

Once the wafers 220 and process trays 214 are within the respective chambers 124, 134 of the first and second load locks 120, 130, and the transfer module robotic arm 118 has been retracted out of the chambers 124, 134, the second doors 128, 138 can close, thereby creating an isolated controlled environment, for example, pressure environment, within the chambers 124, 134. With both the first doors 122, 132 and the second doors 128, 138 closed, the pressure regulators can equalize the pressure within the chambers 124, 134 to create a pressure substantially equal to the atmospheric pressure. Once the desired pressure within chambers 124, 134 has been established, the first doors 122, 132 can be opened, and the wafers 220 and process tray 214 can be removed.

The wafers 220 can then be transferred by the interface robotic arm 148 to a finished wafer cassette 144B, or the wafers 220 can be transferred to the wafer cassette 144A where they originated. The process trays 214 can be transferred by the interface robotic arm 148 to process tray housings 142B or 142A.

One or more of the reaction chambers 102A-F for MOCVD of the chemical vapor deposition system 100 can be replaced with other types of processing chambers. On the epitaxial wafer processing side, one or more of the reaction chambers 102A-F can be CVD reactors for epitaxially growing red, orange, and yellow (ROY) light emitting diodes (for example, gallium arsenide, gallium arsenide phosphide, aluminum gallium indium phosphide, and aluminum gallium arsenide based devices), plasma-enhanced CVD reactor (PECVD), a molecular beam epitaxy (MBE) deposition chamber, an atomic layer deposition (ALD) reactor, a low-pressure CVD reactor (LPCVD), a physical vapor deposition (PVD) reactor, a plasma-enhanced physical vapor deposition (PEPVD) chamber, a thermal annealer, a doping chamber, a plasma-enhanced ALD reactor (PEALD), a plasma-enhanced ALE reactor (PEALE), high density plasma-enhanced chemical vapor deposition (HDPECVD), an atomic layer epitaxy (ALE) chamber, or an etch chamber. Using different types of reaction chambers can increase the efficiency and yield of the chemical vapor deposition system 100.

Each of the one or more reaction chamber pairs 102A/102B, 102C/102D, and/or 102E/102F, load locks 120 and 130, vacuum transfer chamber 108, and/or the automated front-end interface/manual front-end interface 140 can be provided with metrology tools mounted inside or outside of such chambers; for example, on a viewport of one or more of the reaction chambers 102A-F. Examples of metrology tools include in-situ pyrometer/reflectometer, multi-point pyrometer, deflectometer, and/or reflectometer,in-situ pyrometer/deflectometer/reflectometer, elipsometer, photoluminescence spectrometer, electroluminescence spectrometer, surface acoustic wave generator, camera, sensors to measure film thickness, resistivity/doping sensors, electrical characteristics at the wafer level, and surface defects such as particles, cracks, slip, epitaxial growth defects, and the like. Such metrology tools can be used, for example, in testing LED wavelengths during the LED epitaxy processes.

In addition to the epitaxial wafer processing chambers mentioned above, one or more of reaction chambers 102A-F can be replaced by a wafer cleaning processing chamber or a wafer pre-clean or wafer cleaning chamber. A wafer pre-clean or wafer cleaning chamber can be used to remove native oxides (for example, silicon oxide), ionic, metallic, organic (for example, carbon), grease and other impurities (for example, silicon, sapphire, silicon carbide, etc) from wafer 220 surfaces prior to undergoing an epitaxial deposition process in a reaction chamber 102A-F. The pre-cleaning chamber can replace one of the reaction chambers 102A-F of the chemical vapor deposition system 100, or be in communication with the automated front-end interface/equipment front end module/manual front-end interface 140.

During cleaning, a wafer can be moved from a wafer cassette 144 and routed to the pre-clean chamber 102. A cleaning gas, such as chlorine gas (Cl2), hydrogen chloride (HCl), nitrogen trifluoride (NF3), or preferably, hydrogen fluoride (HF), is diluted with an inert carrier gas, such as hydrogen (H2), nitrogen (N2), helium or argon, to form a process cleaning gas. The process cleaning gas is introduced into the pre-clean chamber to contact the surfaces of the wafer 220 to be cleaned. The etchant chemistry reacts with the native oxides and other impurities on the surface of the wafer 220, forming volatile byproduct, such as silicon tetrafluoride (SiF4), and water vapor. The byproduct can be exhausted from the pre-cleaning chamber 102A-F along with any remaining process cleaning gas. The cleaning process can be implemented by heating the process cleaning gas to a temperature ranging from about 20-500° C. Heaters can also be placed in the pre-cleaning chamber to adjust the cleaning process temperature. After cleaning, the cleaned wafer 220 can be moved to a clean wafer cassette 114 to await its sequence for epitaxial growth processes or be moved to a reaction chamber 102 of the chemical vapor deposition system 100 for epitaxial growth processes.

Another component of the present system can be a process tray cleaning chamber. During epitaxial growth processes, epitaxial reaction materials (for example, AlGaN, GaN, Mg, and the like) and other materials can be deposited on the process tray 214 (also referred to as a wafer carrier). If these materials are not removed when new wafers 220 are loaded onto the process tray 214 for a new round of epitaxial growth processes, there is a greater chance of reducing yield and performance for the chemical vapor deposition system 100. In some instances, having the wafer carrier cleaning process chamber attached to the process system will speed up the entire epitaxial process since cleaned process tray 214 will not have to be manually or mechanically brought into the controlled environment (fab) where the process tray cleaning system is located. The wafer carrier cleaning chamber can be attached to the automated front-end interface/equipment front end module/manual front-end interface 140, for example in place of, or in addition to process tray housing 142A.

After epitaxial processing, a processed wafer 220 is normally situated on the process tray 214, the processed wafers 220 can be manually removed or removed by an interface robotic arm 148 and loaded into a wafer cassette 114. This wafer cassette 114 can be moved within the fab for further processing into final semiconductor devices. Once the epitaxial processed wafers 220 are removed from the process tray 214, the process tray 214 can be moved to the wafer carrier cleaning process chamber 142. One or more process trays 214 can be placed in the wafer carrier cleaning process chamber 142. Once the chamber 142A is loaded with one or more process trays 214, a vacuum is applied to the chamber 142A, the chamber interior is heated to a temperature ranging from about 400-1800° C., and a dry gas, for example, hydrogen chloride, chlorine gas, hydrogen, nitrogen, and mixtures thereof, is introduced into the chamber to etch the epitaxial reaction materials from the process tray 214. Once the epitaxial materials are removed from the process tray 214, the cleaned process tray 214 can then be placed into a wafer carrier housing 142B for continued use in the chemical vapor deposition system 100 or returned to the automated front-end interface 140 and mounted on the wafer aligner 152 so that a new wafer 220 can be placed thereon for epitaxial growth in the chemical vapor deposition system 100.

In one embodiment, the wafer carrier process cleaning chamber can replace one of the reaction chambers 102A-F of the chemical vapor deposition system 100 instead of having it attached to the automated front-end interface/equipment front end module/manual front-end interface 140. Other types of methods of cleaning the process tray are well known including using an acid wash (for example, sulfuric acid, citric acid, hydrofluoric acid, hydrochloric acid) or other types of cleaning fluids (for example, hydrogen peroxide, ammonia/water), as well as mixtures of the foregoing, at elevated temperature.

In other embodiments of the chemical vapor deposition system 100, an additional side/facet can be added to chamber 108 such that the epitaxial wafer processing chambers and/or wafer cleaning processing chamber and/or wafer carrier cleaning processing chamber.

In some instances, the automated front-end interface 140 can be replaced with a manual front-end interface. In this instance, wafers 220 are manually loaded or unloaded onto the process tray 214. The manual front-end interface can be a cabinet having a downward flow unit with appropriate filters to remove particles. The cabinet can be in communication with the load locks 120 and 130 and use a lift system to place process trays 214 that are loaded with wafers 220 through a door 122, 132 of each of the load locks 120, 130 and position it on a pedestal within each of the load locks 120, 130. The transfer module robotic arm 118 within vacuum transfer module 108 can then pick up the process trays 214 loaded with wafers 220 and load them into reaction chambers 102A-F. The doors 122, 128, 132, 138 of the load locks 120, 130 can be opened or closed, depending upon whether the load lock 120/130 is being loaded with wafers 220 to be processed or remove wafers 220 that have been processed. Wafer 220 and process tray 214 storage can be provided for in the manual front-end interface and manual or robotic carts can be used to move wafers 220 and/or process trays 214 to various tools within the chemical vapor deposition system 100.

Persons of ordinary skill in the relevant arts will recognize that embodiments may comprise fewer features than illustrated in any individual embodiment described above. The embodiments described herein are not meant to be an exhaustive presentation of the ways in which the various features may be combined. Accordingly, the embodiments are not mutually exclusive combinations of features; rather, embodiments can comprise a combination of different individual features selected from different individual embodiments, as understood by persons of ordinary skill in the art. Moreover, elements described with respect to one embodiment can be implemented in other embodiments even when not described in such embodiments unless otherwise noted. Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended. Furthermore, it is intended also to include features of a claim in any other independent claim even if this claim is not directly made dependent to the independent claim.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

It should be understood that the individual steps used in the methods of the present teachings may be performed in any order and/or simultaneously, as long as the teaching remains operable. Furthermore, it should be understood that the apparatus and methods of the present teachings can include any number, or all, of the described embodiments, as long as the teaching remains operable.

What is claimed is:

1. A chemical vapor deposition system comprising:
an automated front-end interface having a first output and a second output including
a process tray housing configured to house two or more process trays;
a wafer cassette configured to house two or more wafers;
an aligner configured to align a first wafer on a first process tray and a second wafer on a second process tray; and
an interface robotic arm configured to transfer:
the first wafer and the first process tray to the aligner for alignment of the first wafer on the first process tray,
the second wafer and the second process tray to the aligner for alignment of the second wafer on the second process tray,
the aligned first wafer and process tray to the first output, and
the aligned second wafer and process tray to the second output;
a first load lock chamber capable of maintaining a controlled environment, the first load lock having a first door and a second door, the first door being in communication with the first output of the automated front-end interface, wherein the first load lock chamber is configured to receive the aligned first wafer and process tray from the first output through the first door;
a second load lock chamber capable of maintaining a controlled environment, the second load lock having a first door and a second door, the first door being in communication with the second output of the automated front-end interface, wherein the second load lock is configured to receive the aligned second wafer and process tray from the second output through the first door; and
a vacuum transfer module in communication with the second doors of the first and second load lock chambers, the vacuum transfer module having a dual bladed robotic arm configured to manipulate the aligned first wafer and process tray and the aligned second wafer and process tray from the respective first and second load lock chambers to one or more reaction chamber pairs, which are in communication with the vacuum transfer module.

2. The chemical vapor deposition system of claim 1, wherein one or more reaction chambers can perform a process selected from metal organic chemical vapor deposition, chemical vapor deposition, physical vapor deposition, plasma enhanced physical vapor deposition, plasma enhanced chemical vapor deposition, atomic layer deposition, plasma enhanced atomic layer deposition, and atomic layer epitaxy.

3. The chemical vapor deposition system of claim 1, wherein one or more reaction chambers are provided with one or more metrology tools.

4. The chemical vapor deposition system of claim 1, wherein the system includes one pair, two pairs, or three pairs of reaction chambers, where each reaction chamber is independently operated.

5. The chemical vapor deposition system of claim 1, further comprising a source delivery assembly positioned adjacent to each pair of reaction chambers.

6. The chemical vapor deposition system of claim 5, wherein the source delivery assembly is configured to provide a carrier gas, one or more reaction gases, cooling system, and ventilation system for each pair of reaction chambers.

7. The chemical vapor deposition system of claim 1, wherein at least one of the first load lock and second load lock includes at least one shelf, thereby dividing the at least one of the first load lock and second load lock into two or more compartments.

8. The chemical vapor deposition system of claim 7, wherein the controllable environment within the two or more compartments is configured to be independently regulated.

9. A chemical vapor deposition system comprising:
an automated front-end interface having a first output and a second output including—
a process tray housing configured to house two or more process trays;
a wafer cassette configured to house two or more wafers;
an aligner configured to align a first wafer on a first process tray and a second wafer on a second process tray; and
an interface robotic arm configured to transfer wafers and process trays to the aligner, the aligned first wafer and process tray to the first output, and the aligned second wafer and process tray to the second output;
a load lock chamber capable of maintaining a controlled environment and which is in communication with the automated front-end interface having a first door in communication with the first output, a second door in communication with the second output, a third door opposite the first door, and a fourth door opposite the second door, wherein the load lock chamber is configured to receive the aligned first wafer and process tray from the first output through the first door and the aligned second wafer and process tray from the second output through the second door, the load lock chamber including one or more shelves; and
a vacuum transfer module in communication with the third and fourth doors of the load lock chamber, the vacuum transfer module having a dual bladed robotic arm configured to manipulate the aligned first wafer and process tray and the aligned second wafer and process tray from the load lock chamber to one or more reaction chamber pairs which are in communication with the vacuum transfer module.

10. The chemical vapor deposition system of claim 9, wherein one or more reaction chambers can perform a process selected from metal organic chemical vapor deposition, chemical vapor deposition, physical vapor deposition, plasma enhanced physical vapor deposition, plasma enhanced chemical vapor deposition, atomic layer deposition, plasma enhanced atomic layer deposition, and atomic layer epitaxy.

11. The chemical vapor deposition system of claim 9, wherein one or more reaction chambers are provided with one or more metrology tools.

12. The chemical vapor deposition system of claim 9, wherein the system includes one pair, two pairs, or three pairs of reaction chambers, where each reaction chamber is independently operated.

13. A method of preparing a plurality of wafers for the growth of epitaxial layers within a plurality of reaction chambers, the method comprising:
providing an automated front-end interface configured with (i) a wafer cassette configured to house two or more wafers, and (ii) a process tray housing configured to house two or more process trays;
aligning a first wafer from the wafer cassette on a first process tray from the process tray housing via the aligner;
transferring the aligned first wafer and first process tray from the aligner into a first load lock chamber via an interface robotic arm
aligning a second wafer from the wafer cassette on a second process tray from the process tray housing via the aligner; and
transferring the aligned second wafer and second process tray from the aligner into a second load lock chamber via the interface robotic arm.

14. The method of claim 13, further comprising sealing the first load lock chamber and the second load lock chamber and controlling the environment therein.

15. The method of claim 14, wherein the environment is controlled by at least one of establishing a negative pressure environment, maintaining an inert gas environment, maintaining a controlled humidity environment, and maintaining a low particle containing environment.

16. The method of claim 14, further comprising opening respective doors on the first load lock and the second load lock, thereby putting the first load lock chamber and the second load lock chamber in fluid communication with a vacuum transfer module.

17. The method of claim 16, further comprising transferring simultaneously the aligned first wafer and first process tray from the first load lock chamber through the vacuum transfer module and into a first reaction chamber and the aligned second wafer and second process tray from the second load lock chamber through the vacuum transfer module and into a second reaction chamber via a dual bladed robotic arm.

18. The method of claim 17, further comprising processing the aligned first wafer and first process tray in the first reaction chamber and processing the aligned second wafer and second process tray in the second reaction chamber.

19. The method of claim 18, further comprising transferring simultaneously the processed first wafer and first process tray from the first reaction chamber to the first load lock chamber and the processed second wafer and second process tray from the second reaction chamber to the second load lock chamber via the dual bladed robotic arm.
